(19) United States
(12) Patent Application Publication
(10) Pub. No.: US 2026/0005042 A1
(43) Pub. Date: Jan. 1, 2026

(54) SYSTEM AND METHOD FOR SINGULATION OF SEMICONDUCTOR WORKPIECE

(71) Applicant: Intel Corporation, Santa Clara, CA (US)

(72) Inventors: Praveen SREERAMAGIRI, Gilbert, AZ (US); Ibrahim El KHATIB, Chandler, AZ (US); Yi LI, Chandler, AZ (US); Robin McREE, Chandler, AZ (US); Jesse JONES, Chandler, AZ (US); Gang DUAN, Chandler, AZ (US); Manohar KONCHADY, Chandler, AZ (US); Srinivas PIETAMBARAM, Chandler, AZ (US); Yekan WANG, Chandler, AZ (US); Andrew JIMENEZ, Mesa, AZ (US); Aaron GARELICK, Chandler, AZ (US)

(21) Appl. No.: 18/757,615

(22) Filed: Jun. 28, 2024

(51) Int. Cl. H01L 21/67; B23K 26/38; H01L 21/78

(52) U.S. Cl. CPC H01L 21/67092; B23K 26/38; H01L 21/78

(57) ABSTRACT

There may be provided a system. The system may include a workpiece-support assembly that includes a platform positioned alongside a singulation axis of the system. The system may further include a material-removal assembly that includes a cutter, the cutter positioned over the platform and aligned with the singulation axis. The system may further include an irradiation assembly that includes a laser source oriented towards the singulation axis. The system may further include a separation assembly that includes a separation tool. The separation tool may include a first workpiece-engagement member positioned over a first portion of the platform at a first side of the singulation axis and a second workpiece-engagement member positioned over a second portion of the platform at an opposite side of the singulation axis, or an optical source oriented towards the singulation axis.

### BACKGROUND

The increasing focus on advanced packaging technology has driven demand for robust substrate materials, such as glass. Glass offers customizable properties, including adjustable coefficients of thermal expansion, total thickness variation, and adjustable optical characteristics.

However, glass is associated with several challenges due to its inherent brittle nature. Singulating glass substrates poses particular difficulties, as traditional singulation processes would subject glass substrates to significant stresses, resulting in cracks and defects along the substrate edges.

Moreover, ensuring compatibility between singulation processes and diverse substrate types, such as glass combined with other materials, adds another layer of complexity to the process.

Recognizing these issues, there may be a need for an improved system and method for singulating semiconductor workpieces, especially those involving glass.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. In the following description, various aspects are described with reference to the following drawings, in which:

FIG. 1A depicts schematically a top view of a semiconductor workpiece, according to various aspects;

FIG. 1B depicts schematically a cross-sectional view of the semiconductor workpiece, taken along line A-A of FIG. 1A, according to various aspects;

FIG. 1C depicts schematically a top view of the semiconductor workpiece with a build-up layer on its primary faces, according to various aspects;

FIG. 1D depicts schematically a cross-sectional view of the semiconductor workpiece, taken along line AA-AA of FIG. 1C, according to various aspects;

FIG. 2A depicts schematically a top view of the semiconductor workpiece with segments of its protection layer removed, according to various aspects;

FIG. 2B depicts schematically a cross-sectional view of the semiconductor workpiece, taken along line AAA-AAA of FIG. 2A, alongside a material-removal assembly, according to various aspects;

FIG. 2C depicts schematically a top view of the semiconductor workpiece of FIG. 2A with segments of the build-up layer removed, according to various aspects;

FIG. 2D depicts schematically a cross-sectional view of the semiconductor workpiece, taken along line B-B of FIG. 2C, alongside the material-removal assembly, according to various aspects;

FIG. 2E depicts schematically the material-removal assembly having a laser source and a galvanometer scanner, according to various aspects;

FIG. 2F depicts schematically an irradiation assembly irradiating a portion of a substrate of the semiconductor workpiece, according to various aspects;

FIG. 2G to FIG. 2I depict schematically various separation assemblies arranged to separate the semiconductor workpiece, according to various aspects;

FIG. 3 is a block diagram depicting a system, according to various aspects; and

FIG. 4 is a flowchart depicting a method, according to various aspects.

### DETAILED DESCRIPTION

Aspects described below in the context of the apparatus are analogously valid for the respective methods, and vice versa. Furthermore, it will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless the context clearly indicates otherwise. Similarly, the word “or” is intended to include “and” unless the context clearly indicates otherwise.

The system and method described herein present an approach to singulate semiconductor workpieces, especially those utilizing or involving glass, with minimal chipping or fragmentation of a core substrate (e.g. a glass core) of the semiconductor workpiece. The semiconductor workpiece typically features a protection layer, such as an outer protective frame, that allows for handling of the semiconductor workpiece via the frame itself without having to directly engage the glass core. Such semiconductor workpieces are commonly termed “hybrid panels”.

According to various aspects, the system and method described herein offer an efficient solution for singulating such semiconductor workpieces (e.g. hybrid panels) before they advance to die arrangement.

By leveraging laser processes, the system and method, according to the various aspects, can achieve precise singulation, while minimizing risk of cracks and defects in the semiconductor workpiece or its core substrate (e.g. glass core). Specifically, the system and method may involve creating a notch or gap in the protection layer of the semiconductor workpiece, ablating to expose and/or clean the surfaces of the core substrate along a designated singulation axis or “cut street”, perforating the core substrate along the singulation axis to weaken the cut street, and ultimately, singulating or separating the semiconductor workpiece, including the core substrate, along the perforated cut street.

By utilizing non-contact processes, such as laser irradiation, the system and method, according to the various aspects, may minimize abrasive interaction between the semiconductor workpiece and mechanical tools, which can lead to improved package reliability.

Furthermore, singulating semiconductor workpieces, especially those with glass cores, using the system and method described herein provides a cost-effective solution for glass substrate manufacturing.

By integrating laser processes with targeted material removal techniques, the system and method, according to the various aspects, may provide an efficient and reliable solution for handling and singulating semiconductor workpieces, particularly those having glass cores. Consequently, the system and method of the various aspects possess the potential to enhance product quality, increase manufacturing throughput, and advance semiconductor technology.

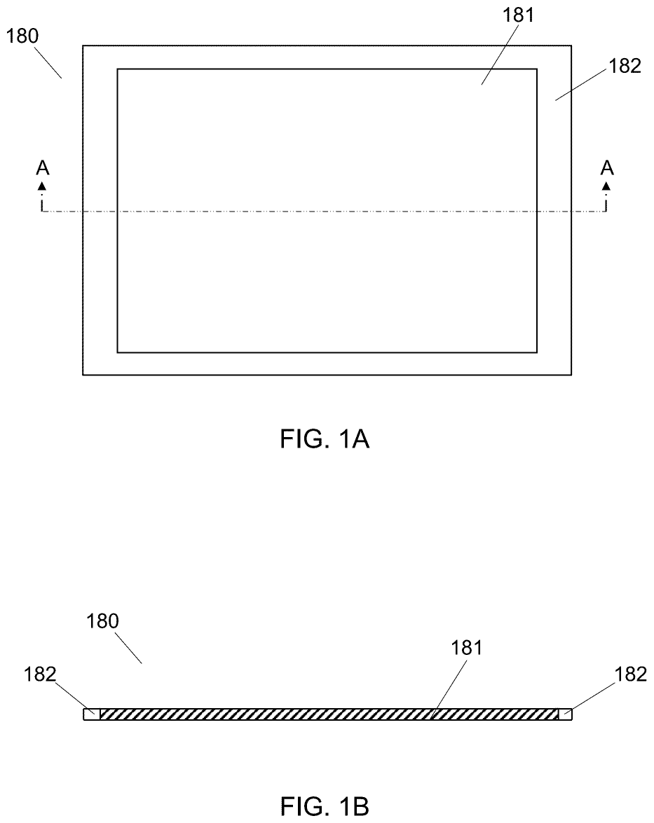

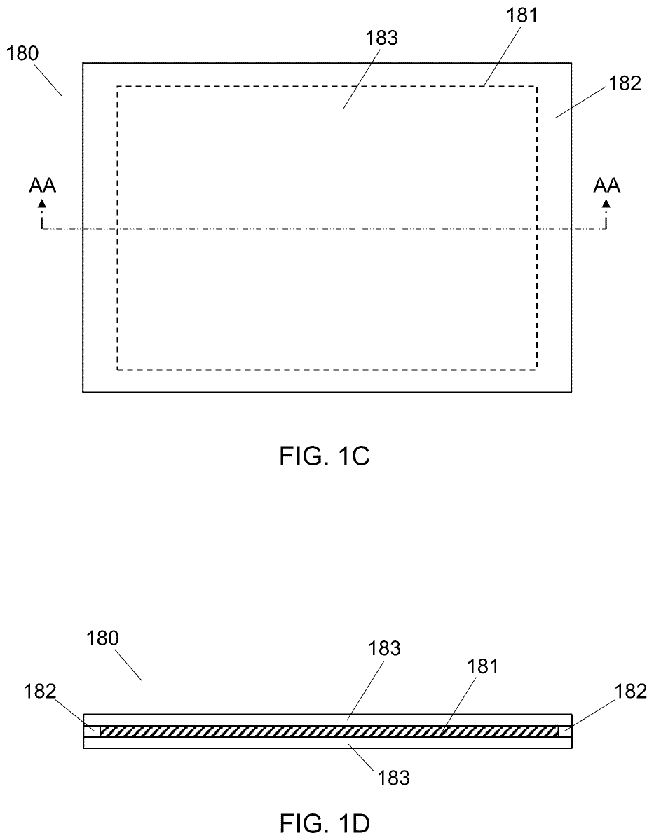

FIG. 1A depicts schematically a top view of a semiconductor workpiece, according to various aspects.

FIG. 1B depicts schematically a cross-sectional view of the semiconductor workpiece, taken along line A-A of FIG. 1A, according to various aspects.

With reference to FIG. 1A and FIG. 1B, according to various aspects, the semiconductor workpiece 180 may include at least a substrate 181 as well as a protection layer 182 on the substrate 181. According to various aspects, the substrate 181 and the protection layer 182 may be distinct components of the semiconductor workpiece 180.

According to various aspects, the substrate 181 may include or may be composed (e.g. composed entirely) of glass (e.g. aluminosilicate or aluminosilicate glass, borosilicate or borosilicate glass, alumino-borosilicate or alumino-borosilicate glass, silica or silica glass, or fused silica or fused silica glass, etc.). According to various aspects, the substrate 181 may be or may include amorphous solid glass. According to various aspects, the substrate 181 (e.g. glass or glass substrate) may include Silicon (Si) and/or Oxygen (O), as well as any one or more of Aluminium (Al), Boron (B), Magnesium (Mg), Calcium (Ca), Barium (Ba), Tin (Sn), Sodium (Na), Potassium (K), Strontium (Sr), Phosphorus (P), Zirconium (Zr), Lithium (Li), Titanium (Ti), and Zinc (Zn). According to various aspects, the substrate 181 (e.g. glass or glass substrate) may include one or more additives, such as Aluminum oxide (Al₂O₃), Boron trioxide (B₂O₃), Magnesium oxide (MgO), Calcium oxide (CaO), Strontium oxide (SrO), Barium oxide (BaO), Tin (IV) oxide (Stannic oxide) (SnO₂), Sodium oxide (Na₂O), Potassium oxide (K₂O), Diphosphorus trioxide (P₂O₃), Zirconium dioxide (ZrO₂), Lithium oxide (Li₂O), Titanium (Ti), and/or Zinc (Zn). According to various aspects, as an example, the substrate 181 (e.g. glass or glass substrate) may include or may compose at least 23% Silicon (Si) and at least 26% Oxygen (O) by weight and, furthermore, may include or compose at least 5% Aluminium (Al) by weight. According to various aspects, the substrate 181 (e.g. glass or glass substrate) may include or may compose inorganic material. According to various aspects, the substrate 181 (e.g. glass or glass substrate) may not include (in other words, may not compose) any organic material, such as organic adhesive.

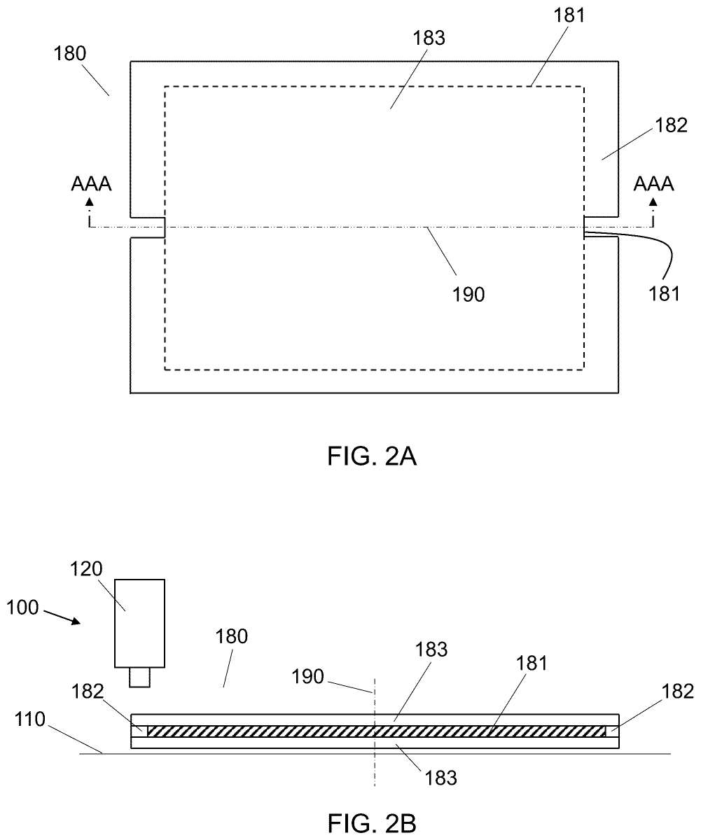

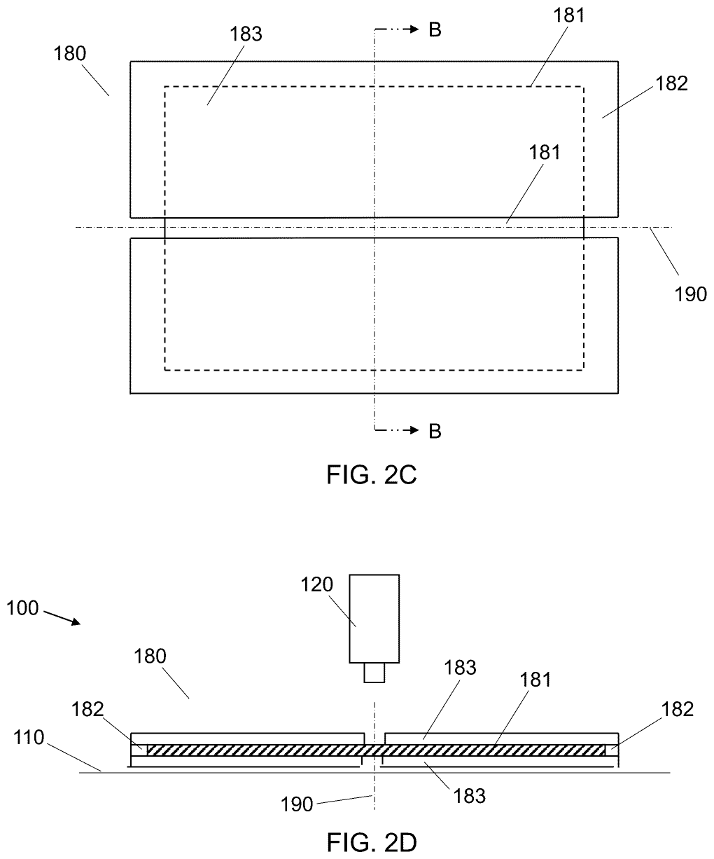

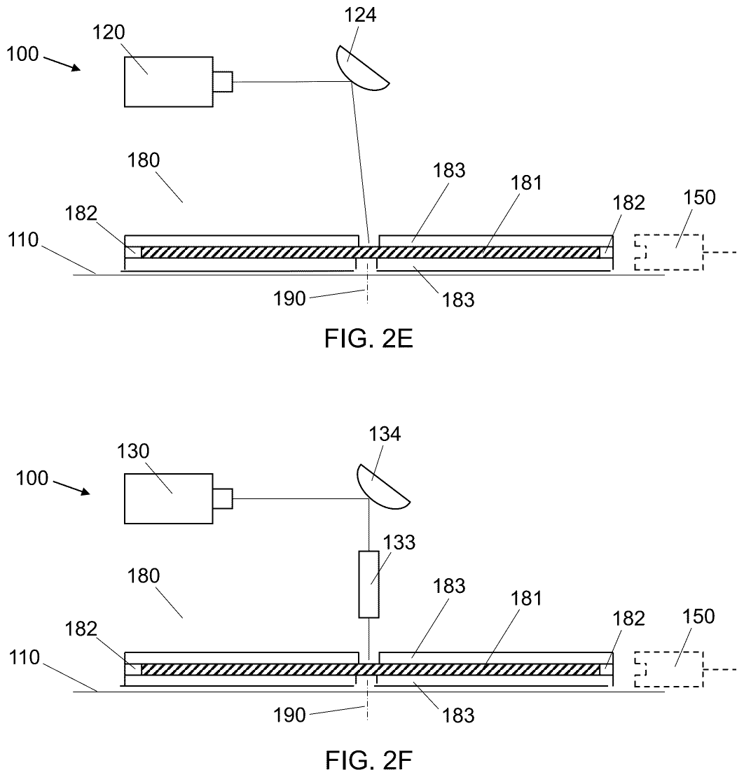

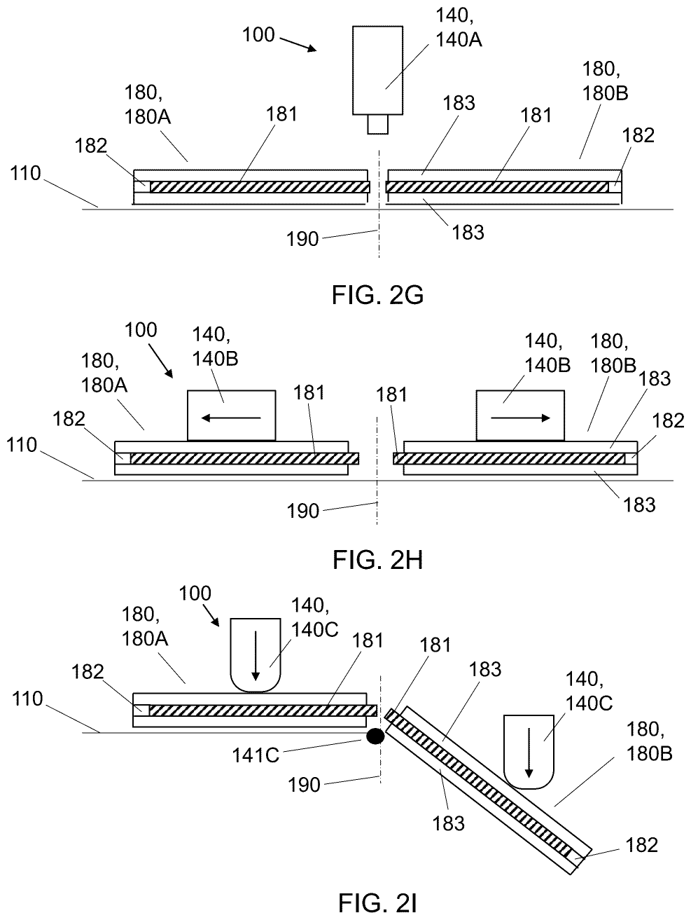

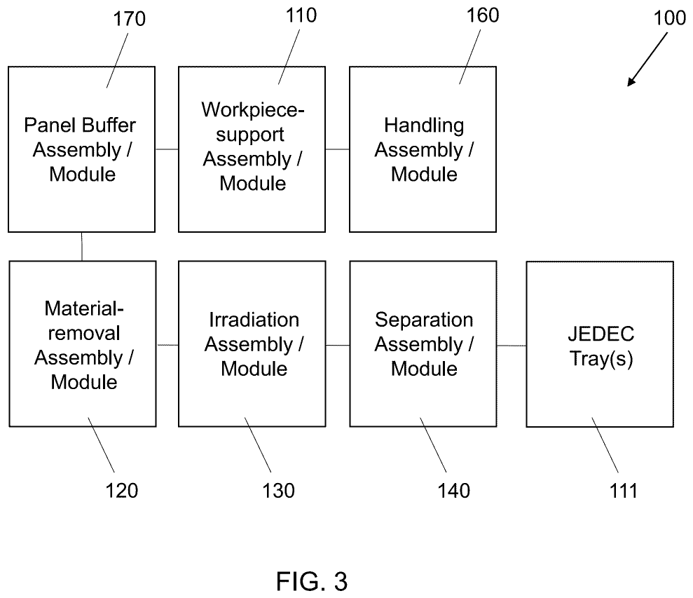

According to various aspects, the substrate 181 (e.g. glass or glass substrate) may be (or may be provided in the form of) a panel (e.g. a square or rectangular shaped panel), a layer (e.g. a glass layer), or a core (e.g. a glass core), etc. As an example, according to various aspects, the substrate 181 (e.g. glass substrate, glass panel, glass layer, or glass core, etc.) may have a thickness ranging between approximately 50 μm to 1.4 mm (in other words, this range may include 50 μm and 1.4 mm). According to various aspects, the substrate 181 (e.g. glass substrate, glass panel, glass layer, or glass core, etc.) may have a first width or length (e.g. measured in a direction parallel to a singulation axis 190, as shown in FIG. 2A, described later) of approximately 10 mm to approximately 520 mm and a second width or length (e.g. measured perpendicular to the first width) of approximately 10 mm to approximately 520 mm. For example, the first width and/or the second width may be approximately 250 mm. According to various aspects, as an example, the substrate 181 may be or may include a square (or squarish) or rectangle (or rectangular) prism volume with section(s) removed (e.g. via(s), through-hole via(s) which may be extending between bottom and upper surfaces of the substrate 181, or blind via(s) which may be extending from the bottom surface or from the upper surface of the substrate 181, etc.) and which may (e.g. may optionally be) filled with other material (e.g. metal, polymer, etc.). In other words, according to various aspects, as an example, the substrate 181 may include at least one via which may include (or may be filled with) material, such as metal and/or polymer.

With reference to FIG. 1A and FIG. 1B, according to various aspects, the substrate 181 may include a “side face”, which may refer to, or may include, or may be any one, more than one (e.g. a sub-set of), or all side surface(s) of the substrate 181. The substrate 181 may also include a top (or an upper) surface as well as a base (or a bottom) surface opposite the top surface (herein may be referred to as “primary faces” of the substrate 181). As depicted in FIG. 1B, the side face of the substrate 181 may be extending between the pair of primary faces of the substrate 181. Furthermore, according to various aspects, these primary faces of the substrate 181 may be, but are not limited to being, planar (e.g. flat) and/or parallel with each other. Accordingly, it is envisaged that, in various other aspects, the primary faces may be non-parallel to each other.

According to various aspects, the protection layer 182 of the semiconductor workpiece 180 may be disposed on the side face (e.g. on only the side face) of the substrate 181 of the semiconductor workpiece 180. While FIG. 1A depicts the protection layer 182 disposed on all side surfaces of the substrate 181, it is envisaged that, according to various other aspects (not shown), the protection layer 182 may (e.g. selectively) be disposed on only one (e.g. a single) or more than one (e.g. a sub-set of the) side surface(s) of the substrate 181. According to various aspects, as an example, depicted in FIG. 1A, the protection layer 182 may encircle or surround (e.g. entirely or completely surround) the substrate 181 (i.e. along its side face, border, or outer peripheral edges). According to various aspects, the protection layer 182 may entirely cover the side face of the substrate 181. Thus, for instance, according to various aspects, a height (or thickness) of the protection layer 182 may correspond to (e.g. may be equal to) a height (or thickness) of the substrate 181 (e.g. measured along a distance parallel to the side face and/or perpendicular to one or both primary face(s) of the substrate 181). It is envisaged that, according to various other aspects (not shown), the height (or thickness) of the protection layer 182 may differ from the height (or thickness) of the substrate 181.

According to various aspects, the protection layer 182 may include or may be composed of a different material (or material composite) from the substrate 181.

According to various aspects, the protection layer 182 may include or may be composed of at least a rigid or substantially rigid material (or material composite), such as a metal or metal alloy (e.g. copper or copper alloy), ceramic, rigid polymer, etc., or any other rigid or substantially rigid material (or material composite). According to various aspects, the protection layer 182 may include (e.g. optionally and/or further include) organic material. Specifically, according to various aspects, the protection layer 182 may include or may be (e.g. may be configured or function as) an organic Copper-Clad-Laminate (CCL) frame.

As an example, according to various aspects, the protection layer 182 may be a protective frame that includes or defines a central opening (e.g. a through-hole opening) that is shaped and/or sized to accommodate (e.g. receive) the substrate 181 therewithin. For instance, a size of the central opening of the protective frame (i.e. protection layer 182) may be larger than a size of the substrate 181. According to various aspects, the central opening and the substrate 181 may correspond (e.g. may be similar or identical) in shape to each other. For instance, they may both be square-shaped or they may both be rectangular-shaped. Accordingly, according to various aspects, the protective frame (i.e. protection layer 182) may be a square annular-shaped protective frame or a rectangular annular-shaped protective frame. It is also envisaged that, in various other aspects (not shown), the protective frame may be a circular annular-shaped protective frame.

According to various aspects, the protection layer 182 may further include a coupling element, such as an adhesive and/or any other suitable coupling element, to couple it to the substrate 181 (e.g. to the side face of the substrate 181). According to various aspects, with the protective frame coupled to the substrate 181, the protection layer 182 may protect the substrate 181 (e.g. a glass core) during handling and processing (e.g. at least before singulation) as well as provide structural reinforcement to the substrate 181.

FIG. 1C depicts schematically a top view of the semiconductor workpiece with a build-up layer on its primary faces, according to various aspects.

FIG. 1D depicts schematically a cross-sectional view of the semiconductor workpiece, taken along line AA-AA of FIG. 1C, according to various aspects.

With reference to FIG. 1C and FIG. 1D, according to various aspects, the semiconductor workpiece 180 may include (e.g. optionally and/or further include) a build-up layer 183 on at least one of the primary faces of the substrate 181. In other words, according to various aspects, the semiconductor workpiece 180 may include a build-up layer 183 on either the bottom surface of the substrate 181 or the top surface of the substrate 181, or may include a respective (e.g. discrete) build-up layer 183 on each of the bottom surface and the top surface of the substrate 181 (in other words, on both primary faces of the substrate 181).

According to various aspects, each build-up layer 183 may cover an entire surface area of a corresponding primary face of the substrate 181. Alternatively, it is envisaged that, according to various other aspects, each build-up layer 183 may partially cover a corresponding primary face of the substrate 181. According to various aspects, each build-up layer 183 may further cover at least a region or portion of the protection layer 182 that is disposed on the side face of the substrate 181.

According to various aspects, each build-up layer 183 may be a single, continuous layer or film of material. Alternatively, according to various other aspects, each build-up layer 183 may be composed of multiple discrete and/or separate elements (or pieces, portions, segments, etc.) of build-up material.

According to various aspects, each build-up layer 183 may include or may be composed of a different material (or material composite) from the protection layer 182.

As some examples, according to various aspects, each build-up layer 183 may include or may be composed of any one or a combination of at least two or more of a polymer (e.g. polyimide), resin, epoxy, adhesive, molding material or molding compound, etc. According to various aspects, each build-up layer 183 may include (e.g. optionally and/or further include) an insulating material, a dielectric material, a heat-resistant material, a flexible material, and/or any other suitable material. According to various aspects, each build-up layer 183 may include or may be composed of organic material, such as Ajinimoto buildup film (ABF). Specifically, according to various aspects, each build-up layer 183 may include or may be ABF.

FIG. 2A depicts schematically a top view of the semiconductor workpiece with segments of its protection layer removed, according to various aspects.

FIG. 2B depicts schematically a cross-sectional view of the semiconductor workpiece, taken along line AAA-AAA of FIG. 2A, alongside a material-removal assembly, according to various aspects.

According to various aspects, there may be provided a system 100 (see, for example, FIG. 3) configured to singulate the semiconductor workpiece 180 into at least two discrete and separate sections (or pieces).

Referring to FIG. 2B, the system 100, according to various aspects, may include a material-removal assembly 120 (or arrangement or unit or module). This material-removal assembly 120 may be configured to form a cut, notch, opening, gap, slit, or similar feature (collectively referred to as “cutoff” for ease of description) in the protection layer 182. According to various aspects, this may be done to facilitate the subsequent singulation (or separation) of the substrate 181.

Specifically, with reference to FIG. 2B, the material-removal assembly 120 may remove “segment(s)” of the protection layer 182 to form the abovementioned “cutoff”.

As shown in FIG. 2A, each segment of the protection layer 182 may align with a singulation axis 190 (e.g. a reference axis), which extends from one side (or point) of the semiconductor workpiece 180 to an opposite side (or point) of the semiconductor workpiece 180. Accordingly, this segment of the protection layer 182 may span from an inner edge of the protection layer 182 to an opposite, outer edge of the protection layer 182. According to various aspects, when the singulation axis 190 is linear or substantially linear, this segment of the protection layer 182 may also be linear or substantially linear. It is also envisaged that, in various other aspects, the singulation axis 190 may be non-linear. As some non-limiting examples, in various other aspects, the singulation axis 190 may adopt a curved configuration or contain one or more curved segments, may be angular or contain one or more angular segments, etc., or may traverse any other non-linear path suitable for the singulation process described herein. Accordingly, the segment of the protection layer 182 (i.e. that is designated for removal) may align with the shape or contour of such a (non-linear) singulation axis 190.

According to various aspects, removing such segment(s) of the protection layer 182 using the material-removal assembly 120 facilitates singulation of the substrate 181 in areas where the substrate 181 lacks the support of the protection layer 182.

As shown in FIG. 2A, according to various aspects, when the semiconductor workpiece 180 includes the protection layer 182 surrounding the substrate 181 along the side face of the substrate 181, the material-removal assembly 120 may be configured to remove “pair(s)” of segments of the protection layer 182, with each pair of segments being positioned opposite (e.g. directly opposite, or substantially opposite) each other. Specifically, each pair of segments of the protection layer 182 may include a first segment of the protection layer 182 at a first side surface (e.g. left side surface) of the substrate 181 and further include a second segment of the protection layer 182 at a second side surface (e.g. right side surface) of the substrate 181, with the pair of segments aligned (e.g. longitudinally aligned) with the singulation axis 190, as shown in FIG. 2A. As shown, the second segment may be opposite (e.g. directly opposite, or substantially opposite) the first segment. Consequently, according to various aspects, when the semiconductor workpiece 180 includes the protection layer 182 surrounding the substrate 181 along the side face of the substrate 181, removing each such pair of segments from the protection layer 182 may result in gaps or breaks in the protection layer 182 which are aligned (e.g. are longitudinally aligned) with the singulation axis 190. As a result of the removal of such a pair of segments from the protection layer 182, the semiconductor workpiece 180 (or the substrate 181 thereof) may be unsupported by any protection layer 182 at the singulation axis 190, to facilitate subsequent singulation or separation of the semiconductor workpiece 180 along the singulation axis 190 itself.

According to various aspects, the material-removal assembly 120 may include a cutter configured to remove the one or more (or “pair(s)” of) segments of the protection layer 182.

As an example, according to various aspects, the cutter of the material-removal assembly 120 may include or may be at least one mechanical cutter (e.g. blade, tool bit, router bit, etc.) configured to remove (e.g. cut, grind, mill, abrade, etc., or machine to remove) the one or more segments of the protection layer 182. For instance, the mechanical cutter may be constructed from a material (or material composite) which is harder than a material of the protection layer 182 of the semiconductor workpiece 180 and the mechanical cutter may be shaped accordingly for its purpose.

As another example, according to various aspects, the cutter of the material-removal assembly 120 may include or may be at least one laser cutter configured to remove one or more segments of the protection layer 182 via irradiation or ablation (e.g. vaporization, or thermal ablation, etc.). For instance, the laser cutter may include or may be a laser source (e.g. at least one laser emitter) configured to emit light or laser (e.g. laser beam(s)) having at least one setting, property, and/or parameter (e.g. wavelength), etc., capable of removing or ablating (e.g. vaporizing, melting, eroding, etc.) the segments of the protection layer 182. According to various aspects, the laser source serving as the laser cutter of the material-removal assembly 120 may be configured to emit a laser that is capable of removing or ablating the protection layer 182, without affecting the substrate 181. In other words, the laser source serving as the laser cutter of the material-removal assembly 120, i.e. that is configured to remove or ablate the protection layer 182, may be incapable of removing or ablating material of the substrate 181 and/or incapable of modifying or altering a structure of the substrate 181.

FIG. 2C depicts schematically a top view of the semiconductor workpiece of FIG. 2A with segments of the build-up layer removed, according to various aspects.

FIG. 2D depicts schematically a cross-sectional view of the semiconductor workpiece, taken along line B-B of FIG. 2C, alongside the material-removal assembly, according to various aspects.

As depicted in FIG. 2A and FIG. 2C, according to various aspects, the semiconductor workpiece 180 may include the build-up layer 183 on at least one of the primary faces (e.g. bottom surface and/or top surface) of the substrate 181.

For ease of description, various aspects herein may be described with reference to the semiconductor workpiece 180 including a build-up layer 183 (e.g. a first build-up layer 183) on a first primary face (e.g. an upper surface) of the substrate 181 and another build-up layer 183 (e.g. a second build-up layer 183) on a second primary face (e.g. a bottom surface) of the substrate 181. Nevertheless, it is envisaged that these aspects are not limited as such and could be extended to other aspects where a semiconductor workpiece 180 includes a single build-up layer 183 on either one of its primary faces.

With reference to FIG. 2B and FIG. 2C, according to various aspects, the material-removal assembly 120 may be further configured to remove at least one segment of each build-up layer 183, with that at least one segment of the build-up layer 183 being aligned with the at least one segment of the protection layer 182 (i.e. that is removed or that is designated for removal, by the material-removal assembly 120) along the singulation axis 190. According to various aspects, removing the at least one segment of each build-up layer 183 would result in at least a region (e.g. underlying region) of each primary face of the substrate 181 along the singulation axis 190 being revealed or exposed, as shown in FIG. 2C. Accordingly, according to various aspects, the material-removal assembly 120 may be configured to ensure that at least a region of each primary face of the substrate 181 along the singulation axis 190 may be clean and devoid of any build-up layer 183.

According to various aspects, as an example, the material-removal assembly 120 may include or may be an etching tool or etching mechanism configured to etch (e.g. chemical etch, plasma etch, wet etch, or dry edge, etc.) the at least one segment of each build-up layer 183 that is aligned with the at least one segment of the protection layer 182 along the singulation axis 190, to remove the at least one segment of the build-up layer 183. According to various aspects, an etchant utilized to etch the build-up layer 183 may selectively etch the build-up layer 183 while being unreactive with the underlying substrate 181. Thus, according to various aspects, the substrate 181 may be resistant to the etchant and may, thus, remain unaffected during the abovesaid etching process.

FIG. 2E depicts schematically the material-removal assembly having a laser source and a galvanometer scanner, according to various aspects.

As another example, according to various aspects, the material-removal assembly 120 of the system 100 may utilize irradiation or ablation to remove the at least one segment of the build-up layer 183. For instance, with reference to FIG. 2E, the material-removal assembly 120 may include or may be a laser source (e.g. at least one laser emitter) configured to emit light or laser (e.g. laser beam(s)) having at least one setting, property, and/or parameter (e.g. wavelength), etc., capable of removing or ablating the at least one segment of the build-up layer 183. According to various aspects, this laser source may be the laser source which may also serve as the laser cutter described earlier. Alternatively, this laser source may be distinct from the laser source which may serve as the laser cutter described earlier. As some examples, the laser source of the material-removal assembly 120 may be configured to emit any one or more of ultraviolet laser, green laser, infrared laser, and/or carbon dioxide laser. Thus, for instance, the laser source of the material-removal assembly 120 may include or may be an ultraviolet laser source, a green laser source, an infrared laser source, and/or a carbon dioxide laser source. In particular, according to various aspects, the ultraviolet laser may have a wavelength within a range of approximately 300 nm to approximately 400 nm, the green laser may have a wavelength within a range of approximately 500 nm to approximately 600 nm, the infrared laser may have a wavelength within a range of approximately 900 nm to approximately 1080 nm, and the carbon dioxide laser may have a wavelength within a range of approximately 10000 nm to approximately 10100 nm. According to various aspects, the laser source of the material-removal assembly 120 may be configured to emit a laser that is capable of removing (e.g. ablating) the build-up layer 183 without affecting the substrate 181 or altering its structure (in other words, is incapable of removing or ablating material of the substrate 181 and/or incapable of modifying or altering a structure of the substrate 181).

Additionally, with reference to FIG. 2E, according to various aspects, the material-removal assembly 120 may include (e.g. optionally and/or further include) a galvanometer scanner 124 to regulate (e.g. control) and/or manipulate the light or laser emitted by the laser source of the material-removal assembly 120. In this configuration, the material-removal assembly 120 may utilize the galvanometer scanner 124 to aim or direct (or to assist in aiming or directing) the light or laser at specific or targeted segment(s) (e.g. of the build-up layer(s) 183). Hence, as an illustration, according to various aspects, the laser emitted by the laser source may be routed through selected optic(s) and (e.g. subsequently) through the galvanometer scanner 124 to precisely guide the laser onto the build-up layer 183, thereby facilitating ablation of the build-up layer 183 from the semiconductor workpiece 180.

It is also envisaged that, according to various aspects, the material-removal assembly 120 (e.g. the entire material-removal assembly 120, or at least its cutter or its laser source) may be movable relative to the semiconductor workpiece 180 (or relative to a workpiece-support assembly 110 of the system 100 which supports the semiconductor workpiece 180).

According to various aspects, the material-removal assembly 120 may be configured to remove the first build-up layer 183 on the first primary face (e.g. upper surface) of the substrate 181 before removing the second build-up layer 183 on the second primary face (e.g. bottom surface) of the substrate 181. For instance, the material-removal assembly 120 may be configured to remove the first build-up layer 183 on the first primary face (e.g. upper surface) of the substrate 181 and, thereafter, with the aid of a flipper or any suitable flipping or repositioning mechanism 150 (e.g. which may optionally be integrated into the system 100), the semiconductor workpiece 180 could be flipped or repositioned to facilitate removal of the second build-up layer 183 on the second primary face (e.g. bottom surface) of the substrate 181 by the material-removal assembly 120.

Alternatively, according to various other aspects, the material-removal assembly 120 may be capable of efficiently removing both the first build-up layer 183 on the first primary face (e.g. upper surface) of the substrate 181 and the second build-up layer 183 on the second primary face (e.g. bottom surface) of the substrate 181 without requiring any flipping or repositioning of the semiconductor workpiece 180. As an example, the material-removal assembly 120 may utilize the laser source to access and target various, different surfaces of the substrate 181 of the semiconductor workpiece 180 (e.g. when the substrate 181 is a glass substrate that is transparent or translucent and permeable to the light or laser emitted by the laser source). As another example, the material-removal assembly 120 may employ a plurality of laser emitters to simultaneously target build-up layers 183 located on both the upper and bottom surfaces of the substrate 181. In this setup, one laser emitter of the material-removal assembly 120 could emit a laser beam to ablate a first build-up layer 183 on the upper surface of the substrate 181, while another laser emitter of the material-removal assembly 120 concurrently ablates a second build-up layer 183 on the bottom surface of the substrate 181.

Consequently, according to various aspects, with the material-removal assembly 120 of the system 100, each primary face of the substrate 181 may be free of or devoid of any build-up layer 183 at least within a region thereof along the singulation axis 190. Consequently, at least a portion (or segment) of the substrate 181 corresponding to the aforementioned region(s) of the (or each) primary face of the substrate 181 may also be free of or devoid of any build-up layer 183. Specifically, with reference to FIG. 2C, the region(s) of each primary face, as well as the corresponding portion (or segment) of the substrate 181 (i.e. which may be free of or devoid of any build-up layer 183), may span or extend from one side of the substrate 181 (i.e. devoid of any protection layer 182, or where protection layer 182 is removed or is designated for removal) to an opposite (e.g. directly opposite, or substantially opposite) side of the substrate 181 (i.e. devoid of any protection layer 182, or where protection layer 182 is removed or is designated for removal). Furthermore, as depicted in FIG. 2C, the region(s) of each primary face as well as the corresponding portion(s) (or segment(s)) of the substrate 181 (i.e. which may be free of or devoid of any build-up layer 183) may be linear or substantially linear.

It is envisaged that, according to various aspects, the material-removal assembly 120 of the system 100 may include any one or more or all of the abovementioned cutter (e.g. for removing protection layer 182), etching tool or etching mechanism (e.g. for removing build-up layer(s) 183), and/or laser source (e.g. for removing protection layer 182 and/or for removing build-up layer(s) 183).

According to various aspects, the material-removal assembly 120 of the system 100 may be configured (e.g. programmed or pre-programmed) to remove (e.g. automatically remove) the at least one segment of the protection layer 182 from the semiconductor workpiece 180 and to remove (e.g. automatically remove) the at least one segment of the build-up layer 183.

For instance, according to various aspects, the material-removal assembly 120 of the system 100 may be configured (e.g. programmed or pre-programmed) to remove (e.g. automatically remove) the at least one segment of the protection layer 182 from the semiconductor workpiece 180 before removing (e.g. before automatically removing) the at least one segment of the build-up layer 183.

As another example, according to various other aspects, the material-removal assembly 120 of the system 100 may be configured (e.g. programmed or pre-programmed) to remove (e.g. automatically remove) the at least one segment of the protection layer 182 from the semiconductor workpiece 180 after removing (e.g. after automatically removing) the at least one segment of the build-up layer 183.

As yet another example, according to various other aspects, the material-removal assembly 120 of the system 100 may be configured (e.g. programmed or pre-programmed) to remove (e.g. automatically remove) both the at least one segment of the protection layer 182 from the semiconductor workpiece 180 and the at least one segment of the build-up layer 183, simultaneously.

FIG. 2F depicts schematically an irradiation assembly of the system irradiating a portion of the substrate of the semiconductor workpiece, according to various aspects.

According to various aspects, the system 100 may include (e.g. further include) an irradiation assembly 130 (or arrangement or unit or module) configured to irradiate at least a portion (or segment) of the substrate 181 at the singulation axis 190 to modify its structure along the singulation axis 190. According to various aspects, these portion(s) (or segment(s)) of the substrate 181 may correspond to (e.g. coincide with) the region(s) of the (or each) primary face which may be free of or devoid of any build-up layer 183. As such, according to various aspects, when the semiconductor workpiece 180 includes the build-up layers 183, the system 100 may be configured to remove at least one segment of each build-up layer 183 along the singulation axis 190, thus revealing or exposing at least a region of each primary face of the substrate 181 along the singulation axis 190. Subsequently, the system 100 may proceed to irradiate at least a portion (or segment) of the (exposed) substrate 181 at the singulation axis 190 to modify its structure (e.g. by creating perforations within the substrate 181, described below) along the singulation axis 190.

According to various aspects, the irradiation assembly 130 of the system 100 may be configured to modify the structure of the substrate 181 along the singulation axis 190 in a manner which weakens the structure of the substrate 181 along the singulation axis 190. According to various aspects, this modified structure of the substrate 181 along the singulation axis 190 may be more susceptible or prone to separation along that singulation axis 190, compared to other portions (or segments) of the substrate 181 which are distant from the singulation axis 190.

To exemplify, according to various aspects, modifying the structure of said portion(s) (or segment(s)) of the substrate 181 at the singulation axis 190 may involve utilizing the irradiation assembly 130 to irradiate the substrate 181 to form or create perforations at (e.g. within and/or on) the substrate 181 at or along the singulation axis 190. In particular, the perforations may be formed at said portion(s) (or segment(s)) of the substrate 181, along an entire length of said portion(s) (or segment(s)) that is aligned with the singulation axis 190. Alternatively, the perforations may be formed at said portion(s) (or segment(s)) of the substrate 181 partially along the length of said portion(s) (or segment(s)) of the substrate 181. According to various aspects, these perforations formed at the substrate 181 may correspond to or may resemble any one or a combination of at least two or more of cavities, voids, spaces, holes, air gaps, apertures, punctures, openings, filaments, dimples (e.g. recesses on the primary face of the substrate 181), etc. Furthermore, according to various aspects, the perforations which are formed may be spaced apart from one another, at equal (or substantially equal) intervals or at non-equal intervals along the singulation axis 190. In particular, according to various aspects, the perforations may be spaced in a manner which distributes a weakening effect across said portion(s) (or segment(s)) of the substrate 181 (i.e. that is aligned with the singulation axis 190), uniformly or variably.

As an example, with reference to FIG. 2F, according to various aspects, the irradiation assembly 130 may include a laser source (e.g. at least one laser emitter). According to various aspects, the laser source utilized by the irradiation assembly 130 may be the laser source which may be utilized by the material-removal assembly 120. Alternatively, the laser source utilized by the irradiation assembly 130 may be distinct from the laser source which may be utilized by the material-removal assembly 120. According to various aspects, the laser source of the irradiation assembly 130 may be configured to irradiate the portion(s) (or segment(s)) of the substrate 181 with light or laser having a first wavelength (or within a first range of wavelengths) capable of modifying the structure of the substrate 181, while the laser source of the material-removal assembly 120 may be configured to irradiate the at least one segment of each build-up layer 183 with light or laser having a second wavelength (or within a second range of wavelengths) capable of removing (e.g. ablating) the at least one segment of the build-up layer 183. According to various aspects, the first wavelength (or first range of wavelengths) may differ from (e.g. may be longer or shorter than) the second wavelength (or second range of wavelengths). Nevertheless, it is envisaged that, according to various other aspects, the first wavelength (or first range of wavelengths) and the second wavelength (or second range of wavelengths) may be similar (e.g. overlapping) or they may be equal in magnitude.

In particular, according to various aspects, the laser source of the irradiation assembly 130 may be configured to emit light or laser (e.g. laser beam(s)) along the singulation axis 190. Furthermore, according to various aspects, the laser source of the irradiation assembly 130 may be configured to emit light or laser (e.g. laser beam(s)) having at least one setting, property, and/or parameter (e.g. wavelength), etc., capable of modifying the structure of the substrate 181 along the singulation axis 190. As some examples, the laser source of the irradiation assembly 130 may be configured to emit any one or more of ultraviolet laser, green laser, infrared laser, and/or carbon dioxide laser, capable of modifying the structure of the substrate 181, creating perforations in the substrate 181.

As an example, according to various aspects, the laser source of the irradiation assembly 130 may include or may be configured as a Filamentation laser source (or emitter) or a Bessel beam source (or emitter). For instance, the laser source of the irradiation assembly 130 may utilize or incorporate Filamentation or Bessel beam shaping optic(s) 133 to produce specific beam profiles, such as Filamentation or Bessel beams. According to various aspects, Filamentation may involve harnessing a “Kerr effect” to attain a self-focused beam within a solid medium, such as the substrate 181 of the semiconductor workpiece 180. This process may entail initial focusing, which may create a plasma to separate material (e.g. of the substrate 181), followed by defocusing and subsequent focusing (e.g. self-focusing) until the structure of the solid medium (e.g. the substrate 181) becomes altered or modified (e.g. having perforations formed therein). On the other hand, Bessel beam emitters may utilize optic(s), such as an axicon or a set of lenses to concentrate a collimated beam (e.g. single collimated beam) into a thin (or thinner) line with high (e.g. very high) aspect ratio which alters or modifies the structure of the solid medium (e.g. the substrate 181). According to various aspects, by controlling the aspect ratio of a beam, a structure of the solid medium (e.g. the substrate 181) may be altered or modified in a single shot of the beam onto the solid medium (e.g. the substrate 181). According to various aspects, this process may be repeated along a designated portion or segment of the substrate 181 (e.g. along the singulation axis 190) to form a curtain or series of perforations (e.g. filaments) within the substrate's 181 structure. According to various aspects, such as a curtain or series of perforations (e.g. filaments) within the substrate's 181 structure at or along the singulation axis 190 may facilitate subsequent separation (i.e. singulation) of the substrate 181 along the singulation axis 190.

Additionally, according to various aspects, with reference to FIG. 2F, the irradiation assembly 130 may include (e.g. optionally and/or further include) a galvanometer scanner 134 for controlling and/or manipulating the light or laser emitted by the laser source of the irradiation assembly 130. Accordingly, the galvanometer scanner 134 may be utilized by the irradiation assembly 130 to direct (or to assist in directing) the light or laser onto specific or targeted portion(s) (or segment(s)) of the substrate 181. It is also envisaged that according to various aspects, the irradiation assembly 130 (e.g. the entire irradiation assembly 130 or at least the laser source) may be movable relative to the semiconductor workpiece 180 (or relative to the workpiece-support assembly 110 of the system 100).

Furthermore, with reference to FIG. 2F, the flipper or repositioning mechanism 150 of the system 100 may (e.g. optionally) be utilized to flip or reposition the semiconductor workpiece 180 to facilitate the irradiation process.

FIG. 2G to FIG. 2I depict schematically various separation assemblies arranged to separate the semiconductor workpiece, according to various aspects.

According to various aspects, the system 100 may include (e.g. further include) a separation assembly 140 configured to separate (i.e. singulate) the semiconductor workpiece 180 at the singulation axis 190.

According to various aspects, the system 100 may be configured (e.g. programmed or pre-programmed) in a manner such that the separation assembly 140 separates (e.g. automatically separates) the semiconductor workpiece 180 at the singulation axis 190 after or upon completion of: (i) removal (e.g. automatic removal) of the at least one segment of the protection layer 182 from the semiconductor workpiece 180 and, if required, removal (e.g. automatic removal) of the at least one segment of the build-up layer 183 (e.g. by the material-removal assembly 120 of the system 100) as well as (ii) modification of the structure of the substrate 181 at the portion(s) (or segment(s)) of the substrate 181 (e.g. via irradiation by the irradiation assembly 130 of the system 100).

Particularly, according to various aspects, the separation assembly 140 may be configured to separate a first section 180A of the semiconductor workpiece 180 from a second section 180B of the semiconductor workpiece 180. According to various aspects, the first section 180A of the semiconductor workpiece 180 may initially be at a first side of the separation axis with at least one edge of the first section 180A bounded by the singulation axis 190 (in other words, the singulation axis 190 may initially coincide with at least one edge of the first section 180A). On the other hand, the second section 180B of the semiconductor workpiece 180 may initially be on an opposite, second side of the separation axis with at least one edge of the second section 180B bounded by the singulation axis 190. Hence, according to various aspects, before the semiconductor workpiece 180 is singulated or separated, said first section 180A of the semiconductor workpiece 180 may be adjacent (e.g. immediately adjacent) and adjoined to the second section 180B of the semiconductor workpiece 180 at the singulation axis 190.

According to various aspects, the separation assembly 140 may be configured to separate the first section 180A and the second section 180B at the singulation axis 190. That is, the first section 180A and the second section 180B may be separated by the separation assembly 140 such that they are no longer adjoined nor in contact, having a gap therebetween.

In particular, according to various aspects, the separation assembly 140 may include a separation tool configured to apply irradiation or to exert mechanical force (e.g. pulling or tensile force, bending force, etc.) onto the semiconductor workpiece 180 to separate the semiconductor workpiece 180 at the singulation axis 190.

As an example, according to various aspects, FIG. 2G depicts a first variation of the separation assembly 140 in which the separation tool of the separation assembly 140 may include an optical source 140A. According to various aspects, the optical source of the separation assembly 140 may be the laser source which may be utilized by the material-removal assembly 120 and/or the irradiation assembly 130. Alternatively, the optical source of the separation assembly 140 may be distinct from the laser source which may be utilized by the material-removal assembly 120 and/or the irradiation assembly 130. According to various aspects, the optical source 140A of the separation assembly 140 may be configured to irradiate or ablate (e.g. vaporize, melt, erode, etc.) the semiconductor workpiece 180 (or at least the substrate 181 thereof) along the singulation axis 190 to separate the semiconductor workpiece 180, into separated first and second sections 180A and 180B, at the singulation axis 190, by emitting laser along the singulation axis 190. Specifically, according to various aspects, the optical source 140A of the separation tool of the separation assembly 140 may emit a laser (e.g. a laser beam) which may induce thermal stresses in the substrate 181 of the semiconductor workpiece 180, along the singulation axis 190, causing the substrate 181 material to expand (e.g. due to being heated) and contract (e.g. upon removal of the heat source), resulting in its separation along the singulation axis 190, while minimizing or preventing chipping or fragmentation.

As another example, according to various aspects, FIG. 2H depicts a second variation of the separation assembly 140 in which the separation tool of the separation assembly 140 may include a pulling mechanism or a pulling tool 140B configured to move or pull apart the semiconductor workpiece 180 so that (or until) the semiconductor workpiece 180 separates or breaks at the singulation axis 190. In particular, the separation tool may be configured to exert a tensile force on the semiconductor workpiece 180 in opposite directions away from the singulation axis 190. For instance, with reference to FIG. 2H, the pulling mechanism 140B of the separation assembly 140 may include a first workpiece-engagement member (e.g. a first clamp or grip) disposed at the first section 180A of the semiconductor workpiece 180 and a second workpiece-engagement member (e.g. a second clamp or grip) disposed at the second section 180B of the semiconductor workpiece 180. According to various aspects, the first workpiece-engagement member may grip, hold, or clamp, etc., onto the first section 180A of the semiconductor workpiece 180, while the second workpiece-engagement member may grip, hold, or clamp, etc., onto the second section 180B of the semiconductor workpiece 180. Thereafter, the pulling mechanism 140B (or first and second workpiece-engagement members thereof) may move or apply forces in opposite directions to separate the first section 180A and the second section 180B of the semiconductor workpiece 180 at the singulation axis 190. Specifically, the first and second workpiece-engagement members may be movable relative to each other in opposite linear directions away from the singulation axis 190. It is also envisaged that, in various other aspects, the first or second workpiece-engagement member may be movable relative to the other, while the other remains stationary.

As yet another example, according to various aspects, FIG. 2I depicts a third variation of the separation assembly 140 in which the separation tool of the separation assembly 140 may include a bending mechanism or a bending tool 140C configured to bend the semiconductor workpiece 180 at or about the singulation axis 190 to break the semiconductor workpiece 180 at the singulation axis 190. Specifically, the bending mechanism 140C may be configured to apply a force to the semiconductor workpiece 180 to induce bending of the semiconductor workpiece 180 about the singulation axis 190. For instance, the bending mechanism 140C of the separation assembly 140 may include the first workpiece-engagement member disposed at the first section 180A of the semiconductor workpiece 180 and the second workpiece-engagement member disposed at the second section 180B of the semiconductor workpiece 180. The first workpiece-engagement member may grip, hold, or clamp, etc., onto the first section 180A of the semiconductor workpiece 180, while the second workpiece-engagement member may grip, hold, or clamp, etc., onto the second section 180B of the semiconductor workpiece 180. Thereafter, the first and second workpiece-engagement members may be movable relative to each other in opposite rotational directions about the singulation axis 190. It is also envisaged that, in various other aspects, the first or second workpiece-engagement member may be movable relative to the other, while the other remains stationary. According to various aspects, the bending mechanism 140C of the separation tool may include a bending element (e.g. bending pin(s) or jig(s)) 141C which may be positioned at one or more points along and/or aligned with the singulation axis 190, and the bending mechanism 140C of the separation tool may exert a mechanical force on the semiconductor workpiece 180 relative to the bending element 141C. According to various aspects, the bending element (e.g. bending pin(s) or bending jig(s)) 141C may be stationary when the mechanical force is applied to the semiconductor workpiece 180 to bend the semiconductor workpiece 180 about the singulation axis 190 (e.g. until the semiconductor workpiece 180 separates or breaks at the singulation axis 190).

It is also envisaged that, according to various aspects, the separation assembly 140 may employ a combination of separation mechanisms. For instance, the separation assembly 140 may be configured to employ both tensile and bending forces simultaneously or sequentially. As an illustration, the separation assembly 140 may first apply tensile forces on the semiconductor workpiece 180 using the pulling mechanism 140B to initiate singulation and then utilize the bending mechanism 140C to complete the singulation by bending the semiconductor workpiece 180 at the singulation axis 190. According to various aspects, this combined approach may enhance the efficiency and effectiveness of the singulation process, ensuring a clean and precise break along the desired axis.

FIG. 3 is a block diagram depicting the system, according to various aspects.

According to various aspects, the system 100 (e.g. a singulation system 100 or a semiconductor-workpiece-singulation system 100) may include at least the material-removal assembly 120 (or arrangement or unit or module), the irradiation assembly 130 (or arrangement or unit or module), and the separation assembly 140 (or arrangement or unit or module) described herein.

According to various aspects, of the system 100, the separation assembly 140 may be downstream of both the material-removal assembly 120 and the irradiation assembly 130. In other words, both the material-removal assembly 120 and the irradiation assembly 130 may be upstream of the separation assembly 140.

According to various aspects, of the system 100, the irradiation may be downstream of the material-removal assembly 120. According to various aspects, the irradiation assembly 130 may be between the material-removal assembly 120 and the separation assembly 140.

According to various aspects, the system 100 may further include (e.g. optionally and/or further include) a panel buffer assembly 170 (or arrangement or unit or module), which may also be referred to as a “panel buffer staging”. According to various aspects, the panel buffer assembly 170 (or panel buffer staging) may be upstream of the material-removal assembly 120 (and/or the irradiation assembly 130 and the separation assembly 140).

According to various aspects, the system 100 may further include (e.g. optionally and/or further include) a handling assembly 160 (or arrangement or unit or module). According to various aspects, as an example, the handling assembly 160 may include or may be one or a combination of at least two or more of a conveyor (e.g. configured to transport or move the semiconductor workpiece 180 from one location to another location within the system 100), handling robot(s), robotic arm(s), manipulator(s), an aligner (e.g. a semiconductor workpiece aligner), sensor(s), identification and tracking (e.g. configured to track an identity and a history of each semiconductor workpiece handled by the system 100), etc. As an example, according to various aspects, the handling assembly 160 may include or may be an Equipment Front End Module (EFEM).

According to various aspects, the system 100 may further include (e.g. optionally and/or further include) one or more Joint Electronic Devices Engineering Council (JEDEC) tray(s) 111.

According to various aspects, the system 100 may further include (e.g. optionally and/or further include) a workpiece-support assembly 110 configured to accommodate or support the semiconductor workpiece 180 thereon. For instance, the workpiece-support assembly 110 may include or may be a stage or a platform, or it may be or may include a portion of the system 100 (or a portion of any assembly, arrangement, unit, or module of the system 100). According to various aspects, the workpiece-support assembly 110 may be positioned alongside the singulation axis 190 of the system 100. For instance, the workpiece-support assembly 110 may be located adjacent and below the singulation axis 190.

As a further illustration, the material-removal assembly 120 (e.g. its cutter) may be positioned over the workpiece-support assembly 110 (e.g. platform) and may be aligned with the singulation axis 190 of the system 100. Furthermore, the irradiation assembly 130 (e.g. its laser source) may be oriented towards the singulation axis 190, so as to be capable of emitting a laser beam towards and/or along the singulation axis 190. The separation assembly 140 (e.g. its separation tool) may be positioned over the workpiece-support assembly 110 and/or oriented towards the singulation axis 190. For instance, the first workpiece-engagement member of the separation assembly 140 may be positioned over a first portion of the workpiece-support assembly 110 at a first side of the singulation axis 190, while the second workpiece-engagement member of the separation assembly 140 may be positioned over a second portion of the workpiece-support assembly 110 at another, opposite side of the singulation axis 190. As another example, the optical source 140A of the separation assembly 140 may be oriented towards the singulation axis 190.

According to various aspects, of the system 100, the handling assembly 160 may be configured to move (e.g. transport) the semiconductor workpiece 180 relative to any one or more or all of the workpiece-support assembly 110, the material-removal assembly 120, the irradiation assembly 130, the separation assembly 140, the panel buffer assembly 170, and/or the JEDEC tray(s) 111. Accordingly, according to various aspects, the handling assembly 160 may be movable relative to any one or more or each (e.g. all) of the workpiece-support assembly 110, the material-removal assembly 120, the irradiation assembly 130, the separation assembly 140, the panel buffer assembly 170, and/or the JEDEC tray(s) 111.

According to various aspects, of the system 100, any two or more of the workpiece-support assembly 110 (e.g. stage or platform), the material-removal assembly 120 (e.g. the cutter, etching tool, and/or the laser source), the irradiation assembly 130 (e.g. the laser source), the separation assembly 140 (e.g. the laser source, bending tool, and/or pulling tool), the panel buffer assembly 170, the handling assembly 160, and/or the JEDEC tray(s) 111 may be movable (e.g. configured to be automatically movable within the system 100) relative to any other assembly, arrangement, unit, or module of the system 100. Thus, for example, the cutter of the material-removal assembly 120 may be configured to move relative to the workpiece-support assembly 110, for instance, along the singulation axis 190 to remove the one or more segments of the protection layer 182 along the singulation axis 190.

According to various aspects, of the system 100, any one or more or each (e.g. all) of the material-removal assembly 120, the irradiation assembly 130, the separation assembly 140, the panel buffer assembly 170, the handling assembly 160, the JEDEC tray(s) 111, and/or the workpiece-support assembly 110 may be a modular sub-assembly (or module) of the system 100. Accordingly, it is envisaged that, according to various aspects, any one or more or each (e.g. all) of the material-removal assembly 120, the irradiation assembly 130, the separation assembly 140, the panel buffer assembly 170, the handling assembly 160, the JEDEC tray(s) 111, and/or the workpiece-support assembly 110 may be positioned (and/or repositioned) within the system 100 in any (e.g. other) suitable manner.

It is also envisaged that, according to various other aspects, within the system 100, any one or more or each (e.g. all) of the material-removal assembly 120, the irradiation assembly 130, the separation assembly 140, the panel buffer assembly 170, the handling assembly 160, the JEDEC tray(s) 111, and/or the workpiece-support assembly 110 may be integral and/or at a fixed position within the system 100.

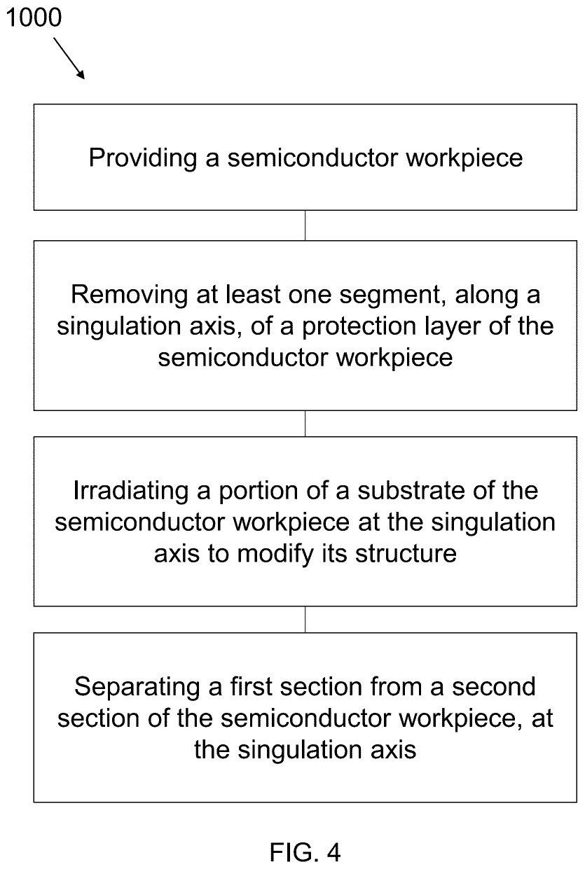

FIG. 4 is a flowchart depicting a method, according to various aspects.

According to various aspects, there may be provided a method 1000 (e.g. a singulation method 1000 or a semiconductor-workpiece-singulation method 1000).

According to various aspects, the method 1000 may include providing the semiconductor workpiece 180. The semiconductor workpiece 180 may include at least the substrate 181 and the protection layer 182 disposed on the side face (e.g. one or more or all side surface(s)) of the substrate 181. According to various aspects, the semiconductor workpiece 180 may be provided on the workpiece-support assembly 110 of the system 100.

According to various aspects, the method 1000 may further include removing at least one segment of the protection layer 182 along the singulation axis 190 (e.g. using the material-removal assembly 120 of the system 100). According to various aspects, the singulation axis 190 may be extending from one side of the semiconductor workpiece 180 to an opposite side of the semiconductor workpiece 180.

According to various aspects, the method 1000 may further include irradiating a portion of the substrate 181 at the singulation axis 190 to modify a structure of the substrate 181 at the singulation axis 190 (e.g. using the irradiation assembly 130 of the system 100).

According to various aspects, the method 1000 may further include separating a first section 180A of the semiconductor workpiece 180 from a second section 180B of the semiconductor workpiece 180 at the singulation axis 190 (e.g. using the separation assembly 140 of the system 100).

According to various aspects, the method 1000 may include (e.g. optionally or further include) chamfering one or more edges or corners of the substrate 181 of the semiconductor workpiece 180 which are not covered (e.g. by the protection layer 182). For instance, the method 1000 may include chamfering one or more exposed edges or corners of the first section 180A and the second section 180B of the semiconductor workpiece 180 after they are separated from each other.

According to various aspects, of the method 1000, removing the at least one segment of the protection layer 182 may involve using the mechanical cutter (e.g. of the material-removal assembly 120 of the system 100) to remove (e.g. cut, grind, mill, abrade, etc., or machine to remove) one or more segments of the protection layer 182.

According to various aspects, of the method 1000, removing the at least one segment of the protection layer 182 may involve using the laser cutter (e.g. of the material-removal assembly 120 of the system 100) to remove one or more segments of the protection layer 182 via irradiation or ablation (e.g. vaporization, or thermal ablation, etc.).

According to various aspects, when the semiconductor workpiece 180 further includes the build-up layer 183 on at least one of the primary faces of the substrate 181, the method 1000 may include etching (e.g. using an etching tool or etching mechanism of the material-removal assembly 120 of the system 100) at least one segment of the build-up layer 183 that is aligned with the at least one segment of the protection layer 182 (i.e. that is removed or designated for removal, by the material-removal assembly 120 of the system 100) along the singulation axis 190, to reveal or expose a region of each of the primary faces (e.g. upper and bottom surfaces) of the substrate 181 along the singulation axis 190.

According to various aspects, when the semiconductor workpiece 180 further includes the build-up layer 183 on at least one of the primary faces (e.g. upper and/or bottom surfaces) of the substrate 181, the method 1000 may include irradiating (e.g. using ultraviolet laser, green laser, infrared laser, or carbon dioxide laser, and/or using the laser source of the material-removal assembly 120) at least one segment of the build-up layer 183 that is aligned with the at least one segment of the protection layer 182 (i.e. that is removed or designated for removal, by the material-removal assembly 120 of the system 100) along the singulation axis 190, to reveal or expose a region of each of the primary faces of the substrate 181 along the singulation axis 190.

According to various aspects, either etching or irradiation (e.g. using the material-removal assembly 120) may be employed to remove one or more segments of the build-up layer 183. It is nevertheless envisaged that, according to various other aspects, both etching and irradiation may be employed to remove one or more segments of the build-up layer 183.

According to various aspects, of the method 1000, irradiating the portion of the substrate 181 at the singulation axis 190 to modify the structure of the substrate 181 at the singulation axis 190 may involve irradiating (e.g. using the irradiation assembly 130 of the system 100) the portion of the substrate 181 at the singulation axis 190 using light or laser with a first wavelength (or within a first range of wavelengths), while irradiating the at least one segment of the build-up layer 183 may involve irradiating (e.g. using the laser source of the material-removal assembly 120 of the system 100) the at least one segment of the build-up layer 183 using light or laser with a second wavelength (or within a second range of wavelengths). According to various aspects, the first wavelength (or first range of wavelengths) may be different from the second wavelength (or second range of wavelengths). According to various other aspects, the first wavelength (or first range of wavelengths) may be equal to the second wavelength (or second range of wavelengths).

According to various aspects, of the method 1000, irradiating the portion of the substrate 181 at the singulation axis 190 to modify the structure of the substrate 181 at the singulation axis 190 may involve forming a plurality of perforations at (e.g. within and/or on) the substrate 181 at or along the singulation axis 190 via irradiation (e.g. using the irradiation assembly 130 of the system 100).

According to various aspects, of the method 1000, separating the first section 180A of the semiconductor workpiece 180 from the second section 180B of the semiconductor workpiece 180 may involve pulling the first section 180A of the semiconductor workpiece 180 and the second section 180B of the semiconductor workpiece 180 away or apart from each other (e.g. until the first section 180A separates from the second section 180B) (e.g. using a pulling mechanism 140B of the separation assembly 140 of the system 100).

According to various aspects, of the method 1000, separating the first section 180A of the semiconductor workpiece 180 from the second section 180B of the semiconductor workpiece 180 may involve bending the semiconductor workpiece 180 about the singulation axis 190 (e.g. until the first section 180A separates or breaks apart from the second section 180B) (e.g. using a bending mechanism 140C of the separation assembly 140 of the system 100). In other words, the method 1000 may include folding the first section 180A of the semiconductor workpiece 180 towards the second section 180B of the semiconductor workpiece 180, or vice versa, about the singulation axis 190, to separate the first section 180A from the second section 180B at the singulation axis 190.

According to various aspects, of the method 1000, separating the first section 180A of the semiconductor workpiece 180 from the second section 180B of the semiconductor workpiece 180 may involve irradiating the semiconductor workpiece 180 along the singulation axis 190 (e.g. using the laser source of the separation assembly 140 of the system 100) (e.g. until the first section 180A separates from the second section 180B).

Various aspects have thus described a system and method capable of efficiently singulating semiconductor workpieces having glass cores.

By integrating laser processes with targeted material removal techniques, the system and method, according to the various aspects, demonstrate enhanced efficiency, reliability, and product quality.

Through minimizing chipping and fragmentation while maintaining structural integrity, this advancement paves the way for improved manufacturing throughput and drives progress in semiconductor technology.

While the disclosure has been particularly shown and described with reference to specific aspects, it should be understood by those skilled in the art that various changes, modification, variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

To more readily understand and put into practical effect the present cleaning assembly, cleaning system, and method, they will now be described by way of examples. For the sake of brevity, duplicate descriptions of features and properties may be omitted.

### Examples

Example 1 provides a system. The system may include a workpiece-support. The workpiece-support assembly may include a platform positioned alongside a singulation axis of the system. The system may further include a material-removal assembly which may include a cutter. The cutter may be positioned over the platform and aligned with the singulation axis. The system may further include an irradiation assembly which may include a laser source that is oriented towards the singulation axis. The system may further include a separation assembly which may include a separation tool. The separation tool may include a first workpiece-engagement member positioned over a first portion of the platform at a first side of the singulation axis and a second workpiece-engagement member positioned over a second portion of the platform at an opposite side of the singulation axis, or an optical source oriented towards the singulation axis.
Example 2 may include the system of example 1 and/or any other example disclosed herein, for which, the cutter may include a laser cutter or a mechanical cutter.
Example 3 may include the system of example 1 and/or any other example disclosed herein, for which, the cutter may include an ultraviolet laser source, a green laser source, an infrared laser source, or a carbon dioxide laser source.
Example 4 may include the system of example 1 and/or any other example disclosed herein, for which, the irradiation assembly may include a Filamentation laser source or a Bessel beam source.
Example 5 may include the system of example 1 and/or any other example disclosed herein, for which, the optical source of the separation tool may include or may be a laser source.
Example 6 may include the system of example 1 and/or any other example disclosed herein, for which, the separation tool may further include a bending jig positioned along the singulation axis.
Example 7 may include the system of example 1 and/or any other example disclosed herein, for which, the first workpiece-engagement member and the second workpiece-engagement member of the separation tool may be movable in opposite directions away from the singulation axis or may be movable in opposite rotational directions about the singulation axis.
Example 8 provides a system. The system may include a workpiece-support assembly or module configured to accommodate a semiconductor workpiece along a singulation axis of the system. The system may further include a material-removal assembly or module which may include a cutter, the cutter configured to move relative to the workpiece-support assembly or module along the singulation axis. The system may further include an irradiation assembly or module which may include a laser source configured to emit a laser beam along the singulation axis. The system may further include a separation assembly or module which may include a separation tool configured to exert mechanical force or apply irradiation to separate the semiconductor workpiece at the singulation axis.
Example 9 may include the system of example 8 and/or any other example disclosed herein, for which, the system may further include a handling assembly or module configured to move the semiconductor workpiece relative to the workpiece-support assembly or module.

As an illustration, any of the aforementioned “module” may refer to a sub-system of the system. As another illustration, any of the aforementioned “module” may refer to a housing or casing that may house or encase one or more components. As another illustration, any of the aforementioned “module” may refer to an arrangement (or assembly) of component(s). As yet another illustration, any of the aforementioned “module” may refer to any equipment (e.g. tool, device, etc.) capable of (or configured) to perform its intended function.
Example 10 provides a method. The method may include providing a semiconductor workpiece which may include a substrate and a protection layer disposed on a side face of the substrate, the side face of the substrate extending between a pair of opposite primary faces of the substrate. The protection layer may include or may be of a different material (e.g. material or material composite) from the substrate. The method may further include removing at least one segment of the protection layer, the at least one segment being aligned and/or along a singulation axis, the singulation axis extending from one side to an opposite side of the semiconductor workpiece. The method may further include irradiating a portion of the substrate at the singulation axis to modify a structure of the substrate at the singulation axis, and thereafter, separating a first section of the semiconductor workpiece from a second section of the semiconductor workpiece, at the singulation axis.
Example 11 may include the system of example 10 and/or any other example disclosed herein, for which, removing the at least one segment of the protection layer may involve using a laser cutter or a mechanical cutter to remove the at least one segment of the protection layer.
Example 12 may include the system of example 10 and/or any other example disclosed herein, for which, the semiconductor workpiece may further include a build-up layer on at least one of the primary faces of the substrate, the build-up layer may include or may be of a different material from the protection layer, and the method may further include irradiating at least one segment of the build-up layer that is aligned with the at least one segment of the protection layer along the singulation axis, to remove the at least one segment of the build-up layer along the singulation axis to expose at least a region of each of the primary faces of the substrate along the singulation axis.
Example 13 may include the system of example 12 and/or any other example disclosed herein, for which, irradiating the at least one segment of the build-up layer may involve using ultraviolet laser, green laser, infrared laser, or carbon dioxide laser to irradiate the at least one segment of the build-up layer.
Example 14 may include the system of example 12 and/or any other example disclosed herein, for which, irradiating the portion of the substrate at the singulation axis to modify the structure of the substrate at the singulation axis may involve using light with a first wavelength to irradiate the portion of the substrate at the singulation axis, while irradiating the at least one segment of the build-up layer may involve using light with a second wavelength to irradiate the at least one segment of the build-up layer. The first wavelength may be different or may differ from the second wavelength.
Example 15 may include the system of example 10 and/or any other example disclosed herein, for which, irradiating the portion of the substrate at the singulation axis to modify the structure of the substrate at the singulation axis may involve or include forming a plurality of perforations at the portion of the substrate via irradiation.
Example 16 may include the system of example 10 and/or any other example disclosed herein, for which, the substrate may be composed of (or may include or may be) glass.
Example 17 may include the system of example 10 and/or any other example disclosed herein, for which, the protection layer may include a metal.
Example 18 may include the system of example 10 and/or any other example disclosed herein, for which, separating the first section of the semiconductor workpiece from the second section of the semiconductor workpiece may involve bending the semiconductor workpiece about the singulation axis.
Example 19 may include the system of example 10 and/or any other example disclosed herein, for which, separating the first section of the semiconductor workpiece from the second section of the semiconductor workpiece may involve pulling the first section of the semiconductor workpiece and the second section of the semiconductor workpiece away from each other.
Example 20 may include the system of example 10 and/or any other example disclosed herein, for which, separating the first section of the semiconductor workpiece from the second section of the semiconductor workpiece may involve irradiating the semiconductor workpiece along the singulation axis.

1. A system comprising:
a workpiece-support assembly comprising a platform positioned alongside a singulation axis of the system;
a material-removal assembly comprising a cutter, the cutter positioned over the platform and aligned with the singulation axis;
an irradiation assembly comprising a laser source that is oriented towards the singulation axis; and
a separation assembly comprising a separation tool, the separation tool comprising
a first workpiece-engagement member positioned over a first portion of the platform at a first side of the singulation axis and a second workpiece-engagement member positioned over a second portion of the platform at an opposite side of the singulation axis, or
an optical source oriented towards the singulation axis.

2. The system of claim 1,
wherein the cutter comprises a laser cutter or a mechanical cutter.

3. The system of claim 1,
wherein the cutter comprises an ultraviolet laser source, a green laser source, an infrared laser source, or a carbon dioxide laser source.

4. The system of claim 1,
wherein the irradiation assembly comprises a Filamentation laser source or a Bessel beam source.

5. The system of claim 1,
wherein the optical source of the separation tool is a laser source.

6. The system of claim 1,
wherein the separation tool further comprises a bending jig positioned along the singulation axis.

7. The system of claim 1,
wherein the first workpiece-engagement member and the second workpiece-engagement member of the separation tool are movable in opposite linear directions away from the singulation axis or are movable in opposite rotational directions about the singulation axis.

8. A system comprising:
a workpiece-support assembly configured to accommodate a semiconductor workpiece along a singulation axis of the system;
a material-removal assembly comprising a cutter, the cutter configured to move relative to the workpiece-support assembly along the singulation axis;
an irradiation assembly comprising a laser source configured to emit a laser beam along the singulation axis; and
a separation assembly comprising a separation tool configured to exert mechanical force or apply irradiation to separate the semiconductor workpiece at the singulation axis.

9. The system of claim 8, further comprising:
a handling assembly configured to move the semiconductor workpiece relative to the workpiece-support assembly.

10. A method comprising:
providing a semiconductor workpiece comprising a substrate and a protection layer disposed on a side face of the substrate, the side face of the substrate extending between a pair of opposite primary faces of the substrate, wherein the protection layer comprises a different material from the substrate;
removing at least one segment of the protection layer, the at least one segment being along a singulation axis, the singulation axis extending from one side to an opposite side of the semiconductor workpiece;
irradiating a portion of the substrate at the singulation axis to modify a structure of the substrate at the singulation axis, and thereafter,
separating a first section of the semiconductor workpiece from a second section of the semiconductor workpiece, at the singulation axis.

11. The method of claim 10,
wherein removing the at least one segment of the protection layer comprises using a laser cutter or a mechanical cutter to remove the at least one segment of the protection layer.

12. The method of claim 10,
wherein the semiconductor workpiece further comprises a build-up layer on at least one of the primary faces of the substrate, wherein the build-up layer comprises a different material from the protection layer;
the method further comprising:
irradiating at least one segment of the build-up layer that is aligned with the at least one segment of the protection layer along the singulation axis, to remove the at least one segment of the build-up layer along the singulation axis to expose at least a region of each of the primary faces of the substrate along the singulation axis.

13. The method of claim 12,
wherein irradiating the at least one segment of the build-up layer comprises using ultraviolet laser, green laser, infrared laser, or carbon dioxide laser to irradiate the at least one segment of the build-up layer.

14. The method of claim 12,
wherein irradiating the portion of the substrate at the singulation axis to modify the structure of the substrate at the singulation axis comprises using light with a first wavelength to irradiate the portion of the substrate at the singulation axis;
wherein irradiating the at least one segment of the build-up layer comprises using light with a second wavelength to irradiate the at least one segment of the build-up layer;
wherein the first wavelength is different form the second wavelength.

15. The method of claim 10,
wherein irradiating the portion of the substrate at the singulation axis to modify the structure of the substrate at the singulation axis comprises forming a plurality of perforations at the portion of the substrate via irradiation.

16. The method of claim 10,
wherein the substrate is composed of glass.

17. The method of claim 10,
wherein the protection layer comprises a metal.

18. The method of claim 10,
wherein separating the first section of the semiconductor workpiece from the second section of the semiconductor workpiece comprises bending the semiconductor workpiece about the singulation axis.

19. The method of claim 10,
wherein separating the first section of the semiconductor workpiece from the second section of the semiconductor workpiece comprises pulling the first section of the semiconductor workpiece and the second section of the semiconductor workpiece away from each other.

20. The method of claim 10,
wherein separating the first section of the semiconductor workpiece from the second section of the semiconductor workpiece comprises irradiating the semiconductor workpiece along the singulation axis.
